(19) United States
(12) Patent Application Publication
(10) Pub. No.: US 2026/0179853 A1
(43) Pub. Date: Jun. 25, 2026

(54) COMPOSITE ELECTRONIC COMPONENT

(71) Applicant: SAMSUNG ELECTRO-MECHANICS CO., LTD., Suwon-si (KR)

(72) Inventors: Jung Won PARK, Suwon-si (KR); Yoo Jeong LEE, Suwon-si (KR); So Jung AN, Suwon-si (KR); So Eun CHOI, Suwon-si (KR); Jong Ho LEE, Suwon-si (KR)

(73) Assignee: SAMSUNG ELECTRO-MECHANICS CO., LTD., Suwon-si (KR)

(21) Appl. No.: 19/330,332

(22) Filed: Sep. 16, 2025

(30) Foreign Application Priority Data
Dec. 24, 2024 (KR) 10-2024-0195147

(51) Int. Cl. H01G 4/30; H01G 4/008

(52) U.S. Cl. CPC H01G 4/30; H01G 4/0085

(57) ABSTRACT

A composite electronic component includes a capacitor including a body, and an external electrode disposed on the body, and a bump disposed on a lower surface side of the body and connected to the external electrode, wherein the external electrode includes an electrode layer in contact with the internal electrode, a Ni plating layer disposed on the electrode layer, a first compound layer disposed on the Ni plating layer, a first Sn plating layer disposed on the first compound layer, a second compound layer disposed on the first Sn plating layer, and a second Sn plating layer disposed on the second compound layer.

### CROSS-REFERENCE TO RELATED APPLICATION(S)

This application claims benefit of priority to Korean Patent Application No. 10-2024-0195147 filed on Dec. 24, 2024 in the Korean Intellectual Property Office, the disclosure of which is incorporated herein by reference in its entirety.

### TECHNICAL FIELD

The present disclosure relates to a composite electronic component.

Multilayer ceramic capacitors (MLCCs) are chip-shaped capacitors mounted on the printed circuit boards of various types of electronic products, such as video display devices such as liquid crystal displays (LCDs) and plasma display panels (PDPs), computers, smartphones and mobile phones, and onboard chargers (OBCs) and DC-DC converters for electric vehicles, to charge or discharge electricity.

Since the dielectric layer included in the multilayer ceramic capacitor has piezoelectricity and electrostriction, when a direct current or alternating current voltage is applied to the multilayer ceramic capacitor, a piezoelectric phenomenon may occur between the internal electrodes, causing vibrations.

This vibration is transmitted to the printed circuit board on which the multilayer ceramic capacitor is mounted through the external electrodes of the multilayer ceramic capacitor, thereby generating a vibration sound. The vibration sound may correspond to an audible frequency within a range of 20 to 20,000 Hz that may be unpleasant to humans, and such unpleasant vibration sound is known as acoustic noise.

In the related art, as a method for reducing acoustic noise, methods such as making the upper cover portion and the lower cover portion of the body different in thickness, combining an interposer containing a ceramic material with the lower part of the capacitor, or combining a metal bump with the lower part of the capacitor were used.

In detail, a structure for combining a metal bump on the lower part of a capacitor, such as in Japanese Patent Application Publication NO. 2022-081609, is a structure in which a Ni plating layer and a Sn plating layer are respectively, repeatedly disposed on the capacitor and the metal pump. In the structure of such a composite electronic component of the related art, an automatic mounting error may occur due to the uneven surface of the metal bump during automatic mounting in which the capacitor is raised on the bump for joining the capacitor and the metal bump. In addition, during the reflow process for joining the capacitor and the metal bump, an excessive and uneven intermetallic compound (IMC) layer may be formed between the Ni plating layer and the Sn plating layer, which may cause agglomeration of the Sn plating layer. In addition, if the Sn plating layer is replated after the reflow process in this state, the thickness of the Sn plating layer in the composite electronic component becomes thicker, which may cause a problem in that the soldering defect rate increases or excessive stress is applied to the composite electronic component when the composite electronic component is mounted on a printed circuit board.

### SUMMARY

An aspect of the present disclosure is to alleviate a problem of mounting defects occurring due to an excessively formed Sn plating layer during a process of coupling capacitors and bumps.

According to an aspect of the present disclosure, a composite electronic component includes a capacitor including a body including a dielectric layer and an internal electrode alternately disposed with the dielectric layer, and an external electrode disposed on the body; and a bump disposed on a lower surface side of the body and connected to the external electrode. The external electrode includes an electrode layer in contact with the internal electrode, a Ni plating layer disposed on the electrode layer, a first compound layer disposed on the Ni plating layer, a first Sn plating layer disposed on the first compound layer, a second compound layer disposed on the first Sn plating layer, and a second Sn plating layer disposed on the second compound layer. The bump includes a main body including a conductive metal, a bump Ni plating layer disposed on the main body, a first bump compound layer disposed on the bump Ni plating layer, a first bump Sn plating layer disposed on the first bump compound layer, a second bump compound layer disposed on the first bump Sn plating layer, and a second bump Sn plating layer disposed on the second bump compound layer.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a perspective view schematically illustrating a composite electronic component according to an embodiment;

FIG. 2 is a cross-sectional view taken along line I-I′ of FIG. 1;

FIG. 3 is a cross-sectional view taken along line II-II′ of FIG. 1;

FIG. 4A and FIG. 4B are schematic views illustrating a process of forming a compound layer in a composite electronic component of the related art;

FIG. 5A and FIG. 5B are schematic views illustrating a process of forming a compound layer in a bump according to an embodiment;

FIG. 6A and FIG. 6B are schematic views illustrating a process of forming a compound layer in a composite electronic component according to an embodiment;

FIG. 7 is a schematic view illustrating an enlarged view of region P of FIG. 2; and

FIG. 8 is a schematic diagram illustrating a method of measuring a 10-point average roughness (Rz) of a first bump compound layer according to an embodiment.

### DETAILED DESCRIPTION

Hereinafter, embodiments will be described with reference to detailed embodiments and the attached drawings. However, the embodiments may be modified in various other forms, and the scope of the present disclosure is not limited to the embodiments described below. In addition, the embodiments are provided to more completely explain the present disclosure to those skilled in the art. Therefore, the shapes and sizes of elements in the drawings may be exaggerated for clearer explanation, and elements indicated by the same symbols in the drawings are the same elements.

In addition, to clearly explain the present disclosure in the drawings, parts that are not related to the explanation are omitted, and the size and thickness of each component illustrated in the drawings are arbitrarily indicated for the convenience of explanation, so the present disclosure is not necessarily limited to what is illustrated. In addition, components with the same functions within the scope of the same idea are described using the same reference symbols. Furthermore, throughout the specification, when a part is said to “include” a component, this does not mean excluding other components, but rather including other components, unless otherwise specifically stated.

In the drawings, the first direction may be defined as the stacking direction or the thickness direction, the second direction as the longitudinal direction, and the third direction as the width direction.

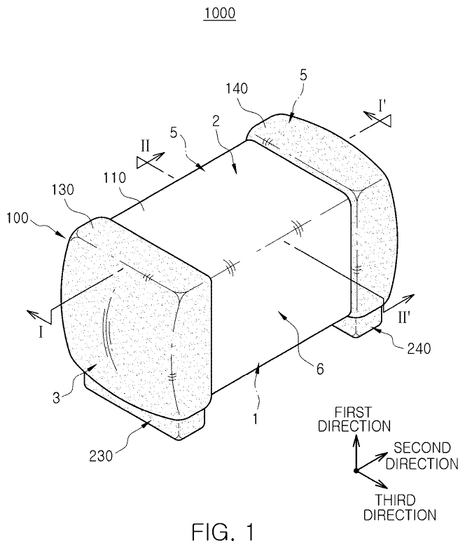

FIG. 1 is a perspective view schematically illustrating a composite electronic component according to an embodiment.

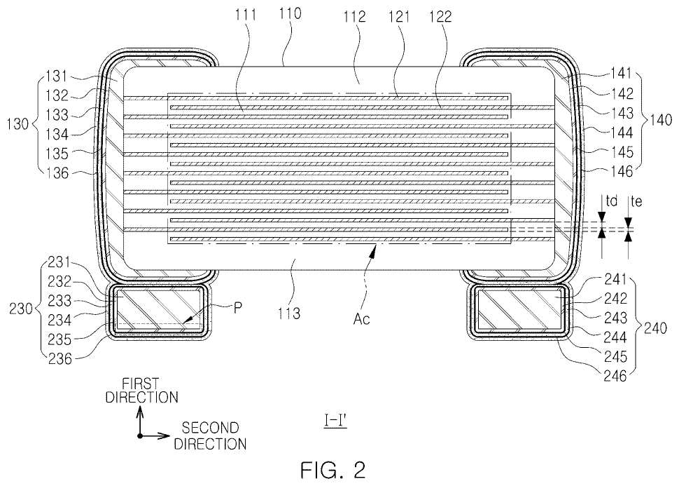

FIG. 2 is a cross-sectional view taken along line I-I′ of FIG. 1.

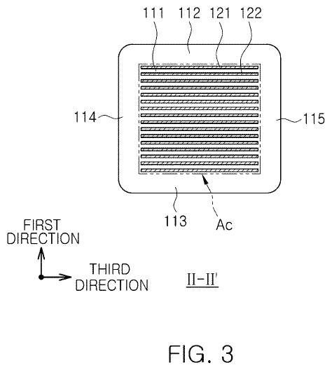

FIG. 3 is a cross-sectional view taken along line II-II′ of FIG. 1.

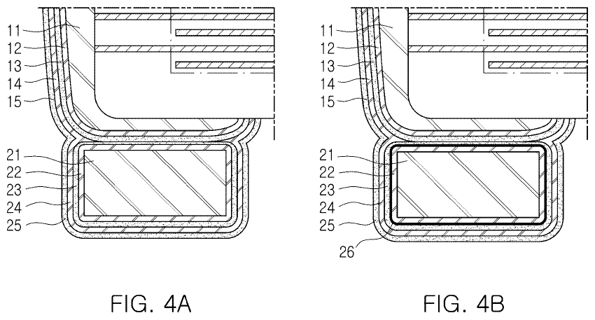

FIG. 4A and FIG. 4B are schematic views illustrating a process of forming a compound layer in a composite electronic component of the related art.

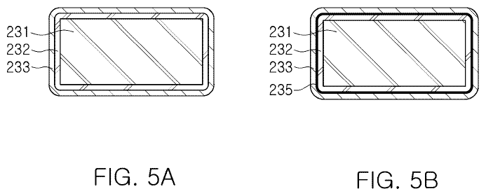

FIG. 5A and FIG. 5B are schematic views illustrating a process of forming a compound layer in a bump according to an embodiment.

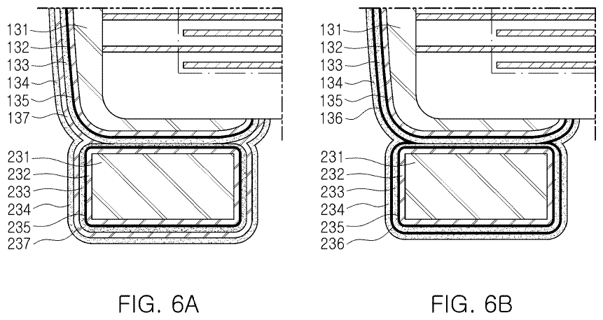

FIG. 6A and FIG. 6B are schematic views illustrating a process of forming a compound layer in a composite electronic component according to an embodiment.

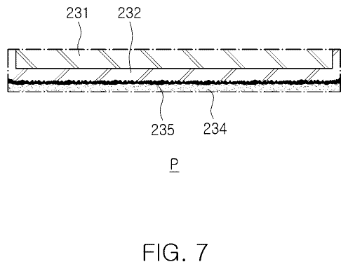

FIG. 7 is a schematic view illustrating an enlarged view of region P of FIG. 2.

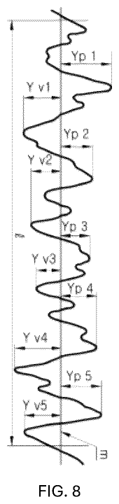

FIG. 8 is a schematic diagram illustrating a method of measuring a 10-point average roughness (Rz) of a first bump compound layer according to an embodiment.

Hereinafter, with reference to FIGS. 1 to 3, 4A, 4B, 5A, 5B, 6A, 6B, 7 and 8, a composite electronic component 1000 according to an embodiment and various embodiments thereof will be described in detail.

A composite electronic component 1000 according to an embodiment includes a capacitor 100 that includes a body 110 including a dielectric layer 111 and internal electrodes 121 and 122 alternately disposed with the dielectric layer, and external electrodes 130 and 140 that are disposed on the body; and bumps 230 and 240 disposed on a lower surface side of the body and connected to the external electrodes. The external electrode may include electrode layers 131 and 141 in contact with the internal electrodes, Ni plating layers 132 and 142 disposed on the electrode layers 131 and 141, first compound layers 135 and 145 disposed on the Ni plating layers 132 and 142, first Sn plating layers 133 and 143 disposed on the first compound layers 135 and 145, second compound layers 136 and 146 disposed on the first Sn plating layers 133 and 143, and second Sn plating layers 134 and 144 disposed on the second compound layers 136 and 146, respectively. The bump 230 and 240 may include main bodies 231 and 241 including a conductive metal, bump Ni plating layers 232 and 242 disposed on the main bodies 231 and 241, first bump compound layers 235 and 245 disposed on the bump Ni plating layers 232 and 242, first bump Sn plating layers 233 and 243 disposed on the first bump compound layers 235 and 245, second bump compound layers 236 and 246 disposed on the first bump Sn plating layers 233 and 243, and second bump Sn plating layers 234 and 244 disposed on the second bump compound layers 236 and 246, respectively.

The capacitor 100 may include a body 110 and external electrodes 130 and 140 disposed on the body.

The body 110 may include a dielectric layer 111 and internal electrodes 121 and 122, and the dielectric layer 111 and the internal electrodes 121 and 122 may be alternately disposed in a first direction. For example, in the present disclosure, the first direction may refer to a stacking direction of the dielectric layer 111 and the internal electrodes 121 and 122.

There is no particular limitation on the detailed shape of the body 110, but as illustrated in FIG. 1, the body 110 may be formed in a hexahedral shape or a similar shape. Due to shrinkage of the ceramic powder included in the body 110 during the firing process, the body 110 may not have a hexahedral shape with perfect straight lines, but may have a substantially hexahedral shape.

The body 110 may have first and second surfaces 1 and 2 opposing each other in a first direction, third and fourth surfaces 3 and 4 connected to the first and second surfaces 1 and 2 and opposing each other in a second direction that is perpendicular to the first direction, and fifth and sixth surfaces 5 and 6 connected to the first and second surfaces 1 and 2, connected to the third and fourth surfaces 3 and 4, and opposing each other in a third direction that is perpendicular to the first and second directions.

Meanwhile, since margin areas in which the internal electrodes 121 and 122 are not disposed on the dielectric layers 111 overlap each other, a step is generated due to the thickness of the internal electrodes 121 and 122, and an edge connecting the first surface and the third to sixth surfaces and/or an edge connecting the second surface and the third to sixth surfaces may have a shape that is contracted toward the center of the body 110 in the first direction of the body 110 when viewed from the first surface or the second surface. Alternatively, due to contraction behavior during the sintering process of the body, an edge connecting the first surface 1 and the third to sixth surfaces 3, 4, 5 and 6 and/or an edge connecting the second surface 2 and the third to sixth surfaces 3, 4, 5 and 6 may have a shape that is contracted toward the center of the body 110 in the first direction of the body 110 when viewed from the first surface or the second surface. Alternatively, to prevent chipping defects or the like, edges connecting respective surfaces of the body 110 may be rounded by performing a separate process, so that the edges connecting the first surface and the third to sixth surfaces and/or the edges connecting the second surface and the third to sixth surfaces may have a round shape.

The plurality of dielectric layers 111 forming the body 110 are in a fired state, and the boundary between adjacent dielectric layers 111 may be integrated to the extent that it is difficult to confirm without using a scanning electron microscope (SEM). The number of stacks of dielectric layers need not be particularly limited, and may be determined in consideration of the size of the composite electronic component. For example, the body may be formed by stacking 400 or more dielectric layers.

The dielectric layer 111 may be formed by manufacturing a ceramic slurry containing ceramic powder, an organic solvent, and a binder, applying and drying the slurry on a carrier film to prepare a ceramic green sheet, and then firing the ceramic green sheet. The ceramic powder is not particularly limited as long as it may obtain sufficient electrostatic capacitance, but, for example, barium titanate-based (BaTiO₃) powder may be used as the ceramic powder. For a more detailed example, the barium titanate (BaTiO₃) powder may be at least one selected from the group consisting of BaTiO₃, (Ba₁₋ₓCaₓ)TiO₃ (0<x<1), Ba(Ti_{1-y}Ca_{y})O3 (0<y<1), (Ba₁₋ₓCaₓ)(Ti_{1-y}Zr_{y})O₃ (0<x<1, 0<y<1), and Ba(Ti_{1-y}Zr_{y})O₃ (0<y<1), and the CaZrO₃-based paraelectric powder may be (Ca₁₋ₓSrₓ)(Zr_{1-y}Ti_{y})O₃ (0<x<1, 0<y<1).

The average thickness (td) of the dielectric layer 111 is not particularly limited.

To miniaturize and increase the capacitance of the composite electronic component 1000, the average thickness (td) of the dielectric layer 111 may be 0.35 μm or less, and to improve the reliability of the composite electronic component 1000 under high temperature and high pressure, the average thickness (td) of the dielectric layer 111 may be 3 μm or more.

The average thickness (td) of the dielectric layer 111 may refer to the average thickness of at least one dielectric layer among a plurality of dielectric layers.

The average thickness (td) of the dielectric layer 111 may be measured by scanning an image of the first and second direction cross section (L-T cross section) of the body 110 using a scanning electron microscope (SEM). For example, the average thickness (td) of the dielectric layer 111 may be a value obtained by scanning and obtaining an image of the first and second direction (L-T) cross-section cut from the center of the width direction of the body 110 using a scanning electron microscope (SEM), and averaging the thicknesses measured at a ¼ points, a 2/4 point, and a ¾ point, provided by dividing the dielectric layer into four parts in the longitudinal direction, based on the dielectric layer of one layer adjacent to the point at which the longitudinal center line and the thickness direction center line of the capacitance forming portion meet in the obtained image. If this measurement is extended to the upper two and lower two dielectric layers having equal intervals based on the dielectric layer of one layer adjacent to the point at which the longitudinal center line and the thickness direction center line of the capacitance forming portion meet, the average thickness of the dielectric layer may be further generalized.

The body 110 may include a capacitance forming portion (Ac) which is disposed inside the body 110 and in which a capacitance is formed by including a first internal electrode 121 and a second internal electrode 122 that are alternately disposed with a dielectric layer 111, and cover portions 112 and 113 formed above and below the capacitance forming portion (Ac) in the first direction.

The capacitance forming portion (Ac) is a portion that contributes to the formation of the capacitance of the capacitor, and may be formed by repeatedly stacking a plurality of first and second internal electrodes 121 and 122 with a dielectric layer 111 therebetween, and may refer to an area in which the first and second internal electrodes 121 and 122 overlap in the first direction. In addition, the first internal electrode 121 may be disposed at the top end of the capacitance forming portion (Ac) in the first direction, and the second internal electrode 122 may be disposed at the bottom end thereof in the first direction.

The internal electrodes 121 and 122 may include first and second internal electrodes 121 and 122. The first and second internal electrodes 121 and 122 may be alternately disposed with the dielectric layer 111 forming the body 110 and interposed therebetween, to face each other, and may be exposed to the third and fourth surfaces 3 and 4 of the body 110, respectively. For example, in an embodiment, the first internal electrode 121 may have one end in the second direction in contact with the third surface 3, and the second internal electrode 122 may have one end in the second direction in contact with the fourth surface 4.

Referring to FIG. 2, the first internal electrode 121 may be connected to the first external electrode 130, and the second internal electrode 122 may be connected to the second external electrode 140.

The first internal electrode 121 may be connected to the first external electrode 130 without being connected to the second external electrode 140, and the second internal electrode 122 may be connected to the second external electrode 140 without being connected to the first external electrode 130. For example, the first internal electrode 121 may be formed at a certain distance from the fourth surface 4, and the second internal electrode 122 may be formed at a certain distance from the third surface 3. In addition, the first and second internal electrodes 121 and 122 may be disposed at a certain distance from the fifth and sixth surfaces of the body 110.

The conductive metal included in the internal electrodes 121 and 122 may be at least one selected from the group consisting of Ni, Cu, Pd, Ag, Au, Pt, In, Sn, Al, Ti, and alloys thereof, and the present disclosure is not limited thereto.

The average thickness (te) of the internal electrodes 121 and 122 is not particularly limited and may vary depending on the purpose. To miniaturize the composite electronic component 1000, the average thickness (te) of the internal electrodes 121 and 122 may be 0.35 μm or less, and to improve the reliability of the composite electronic component 1000 under high temperature and high pressure, the average thickness (te) of the internal electrodes 121 and 122 may be 3 μm or more.

The average thickness (te) of the internal electrodes 121 and 122 may refer to the average thickness of at least one or more internal electrodes among a plurality of internal electrodes.

The average thickness (te) of the internal electrodes 121 and 122 may be measured by scanning the image of the first and second direction cross-section (L-T cross-section) of the body 110 using a scanning electron microscope (SEM). For example, the average thickness (te) of the internal electrodes 121 and 122 may be a value obtained by averaging the thicknesses measured at a ¼ point, a 2/4 point, and a ¾ point when dividing the internal electrode into four parts in the longitudinal direction, based on the internal electrode of one layer adjacent to the point at which the longitudinal center line and the thickness direction center line of the capacitance forming portion of the internal electrode meet, in the image of the first and second direction (L-T) cross-section cut from the center of the width direction of the body 110 scanned using a scanning electron microscope (SEM). If this measurement is extended to the upper two and lower two internal electrodes having equal spacing based on the internal electrode of one layer adjacent to the point at which the longitudinal center line and the thickness direction center line of the capacitance forming portion meet, the average thickness of the internal electrode may be further generalized.

Referring to FIG. 2, the cover portions 112 and 113 may be disposed on the upper surface and lower surface of the capacitance forming portion (Ac) in the first direction.

The cover portions 112 and 113 may basically play a role in preventing damage to the internal electrode due to physical or chemical stress.

The cover portions 112 and 113 may include the same material as a material of the dielectric layer 111. For example, the cover portions 112 and 113 may include a ceramic material, for example, a barium titanate (BaTiO₃)-based ceramic material.

Meanwhile, the thickness of the cover portions 112 and 113 does not need to be particularly limited. For example, the thickness of the cover portions 112 and 113 may be 20 μm or less, respectively.

The average thickness of the cover portions 112 and 113 may refer to the size in the first direction, and may be an average value of the first direction size of the cover portions 112 and 113 measured at five equally spaced points above or below the capacitance forming portion (Ac).

Referring to FIG. 3, margin portions 114 and 115 may be disposed on the side surfaces of the capacitance forming portion (Ac).

The margin portions 114 and 115 may include a first margin portion 114 disposed on the fifth surface 5 of the body 110 and a second margin portion 115 disposed on the sixth surface 6. For example, the margin portions 114 and 115 may be disposed on both end surfaces of the ceramic body 110 in the width direction.

As illustrated in FIG. 3, the margin portions 114 and 115 may refer to areas between both ends of the first and second internal electrodes 121 and 122 and the boundary surface of the body 110 in a cross-section of the body 110 cut in the width-thickness (W-T) direction.

The margin portions 114 and 115 may basically play a role in preventing damage to the internal electrode due to physical or chemical stress.

The margin portions 114 and 115 may be formed by forming the internal electrode by applying a conductive paste except for the area in which the margin portion is to be formed on the ceramic green sheet.

Meanwhile, the width of the margin portions 114 and 115 need not be particularly limited. For example, the average width of the margin portions 114 and 115 may be 20 μm or less, respectively.

The average width of the margin portions 114 and 115 may refer to the average size of the area in the third direction, in which the internal electrode is spaced from the fifth surface, and the average size of the area in the third direction, in which the internal electrode is spaced from the sixth surface, and may be an average value of the third direction sizes of the margin portions 114 and 115 measured at five equally spaced points on the side surface of the capacitance forming portion (Ac).

The external electrodes 130 and 140 may be disposed on the body 110, and in detail, may be disposed on the third surface 3 and the fourth surface 4 of the body 110.

The external electrodes 130 and 140 may include a first external electrode 130 disposed on the third surface 3 of the body 110 and a second external electrode 140 disposed on the fourth surface 4 of the body 110.

Meanwhile, the external electrodes 130 and 140 need not be limited to being disposed only on the third surface 3 and the fourth surface 4 of the body. Referring to FIGS. 1 and 2, the first external electrode 130 may be disposed by extending from the third surface 3 of the body 110 to portions of the first, second, fifth, and sixth surfaces 1, 2, 5 and 6, and the second external electrode 140 may be disposed by extending from the fourth surface 4 to portions of the first, second, fifth, and sixth surfaces 1, 2, 5 and 6.

The external electrodes 130 and 140 may include electrode layers 131 and 141 disposed on the body 110 and connected to the internal electrodes 121 and 122.

In detail, the first external electrode 130 may include a first electrode layer 131 disposed on the body 110 and connected to the first internal electrode 121, and the second external electrode 140 may include a second electrode layer 141 disposed on the body 110 and connected to the second internal electrode 122.

The first and second electrode layers 131 and 141 may be connected to the internal electrodes 121 and 122, respectively, and may play a role in securing electrical connectivity between the external electrodes 130 and 140 and the internal electrodes 121 and 122.

The first electrode layer 131 and the second electrode layer 141 may include a conductive metal. A material having excellent electrical conductivity may be used as the conductive metal, and is not particularly limited. For example, the conductive metal may be at least one selected from the group consisting of nickel (Ni), copper (Cu), and alloys thereof, and the electrode layers 131 and 141 may include Cu to secure electrical conductivity and bonding strength through alloy formation with the Ni internal electrode.

For more detailed examples of the first and second electrode layers 131 and 141, the electrode layers may be sintered electrodes including a conductive metal and glass, or resin-based electrodes including a conductive metal and resin.

The first and second electrode layers 131 and 141 may be in the form of sintered electrodes and resin-based electrodes sequentially formed on the body. In addition, the electrode layers may be formed by transferring a sheet including a conductive metal onto the body, or may be formed by transferring a sheet including a conductive metal onto the sintered electrode.

A plating layer may be disposed on the electrode layers 131 and 141. The plating layer may play a role in improving the sealing and mounting properties of the composite electronic component 1000, and may play a role in improving the bonding strength with the bumps 230 and 240 described later. The detailed structure of the plating layer will be described later.

Meanwhile, the method of forming the plating layer is not particularly limited, and various methods such as electroless plating and electrolytic plating may be used.

The bumps 230 and 240 are disposed on the lower surface side of the capacitor 100 and may be connected to the external electrodes 130 and 140. The bumps 230 and 240 are disposed on the lower surface side of the capacitor 100 and may play a role in reducing or absorbing vibrations transmitted from the substrate to the capacitor 100.

The bumps 230 and 240 may include a component that does not melt even during the solder reflow process, and may have multiple layers to facilitate adhesion to the capacitor 100.

According to an embodiment, the bumps 230 and 240 may include main bodies 231 and 241 including a conductive metal, and the type of the conductive metal included in the main bodies 231 and 241 is not particularly limited, but when the main bodies 231 and 241 includes Cu as the conductive metal, the effect of suppressing or absorbing vibrations may be more excellent.

Meanwhile, since the bumps 230 and 240 itself according to an embodiment performs the role of an electrode, the electrical conductivity may be excellent. In detail, the main bodies 231 and 241 may be substantially comprised only of a conductive metal. For example, the main bodies 231 and 241 may include Cu and O, but the content of O included in the main bodies 231 and 241 may be at a level of 0.5 at % or less relative to Cu and may be more than 0.01 at %.

Referring to FIG. 4A, in a composite electronic component of the related art, a capacitor may have a structure in which Ni plating layers 12 and 14 and Sn plating layers 13 and 15 are sequentially disposed on an electrode layer 11 and which is joined to a bump in which Ni plating layers 22 and 24 and Sn plating layers 23 and 25 are sequentially disposed on a main body 21. When a reflow process is performed at a temperature of about 270° C. to mount such a composite electronic component of the related art on a substrate, as illustrated in FIG. 4B, a thick and non-uniform intermetallic compound layer 26 may be formed between the Ni plating layer 22 and the Sn plating layer 23 disposed on the bump main body 21. Accordingly, other plating layers 23, 24 and 25 disposed on the intermetallic compound layer 26 are also likely to be formed unevenly along the surface shape of the intermetallic compound layer 26, which increases the probability of agglomeration of the outermost Sn plating layer 25 directly involved in mounting, resulting in problems such as reduced mounting performance of the composite electronic component and increased stress applied to the composite electronic component.

Referring to FIG. 2, external electrodes 130 and 140 in an embodiment of the present disclosure includes electrode layers 131 and 141 in contact with internal electrodes 121 and 122, Ni plating layers 132 and 142 disposed on the electrode layers 131 and 141, first compound layers 135 and 145 disposed on the Ni plating layers 132 and 142, first Sn plating layers 133 and 143 disposed on the first compound layers 135 and 145, second compound layers 136 and 146 disposed on the first Sn plating layers 133 and 143, and second Sn plating layers 134 and 144 disposed on the second compound layers 136 and 146. The bumps 230 and 240 may include main bodies 231 and 241 including a conductive metal, bump Ni plating layers 232 and 242 disposed on the main bodies 231 and 241, first bump compound layers 235 and 245 disposed on the bump Ni plating layers 232 and 242, first bump Sn plating layers 233 and 243 disposed on the first bump compound layers 235 and 245, second bump compound layers 236 and 246 disposed on the first bump Sn plating layers 233 and 243, and second bump Sn plating layers 234 and 244 disposed on the second bump compound layers 236 and 246.

Through this structure, the first compound layers 135 and 145 and the first bump compound layers 235 and 245 may be uniformly formed, and the agglomeration of Sn plating layers disposed on the first compound layers 135 and 145 and the first bump compound layers 235 and 245 may be prevented, and the recognition error of Surface Mount Technology (SMT) equipment that may occur when mounting a composite electronic component 1000 on a substrate may be prevented.

In addition, by forming second compound layers 136 and 146 between the first Sn plating layers 133 and 143 and the second Sn plating layers 134 and 144, and second bump compound layers 236 and 246 between the first bump Sn plating layers 233 and 243 and the second bump Sn plating layers 234 and 244, an increase in the volume of the outermost Sn plating layer due to re-plating of the Sn plating layer may be suppressed. Accordingly, a problem of soldering failure that may occur during the process of mounting the composite electronic component 1000 on a substrate or a problem of excessive stress being applied to the composite electronic component 1000 may be effectively alleviated.

The second compound layers 136 and 146 may be disposed between the first Sn plating layers 133 and 143 and the second Sn plating layers 134 and 144. For example, the first Sn plating layers 133 and 143 and the second Sn plating layers 134 and 144 may be in contact with the second compound layers 136 and 146.

Similarly, the second bump compound layers 236 and 246 may be disposed between the first bump Sn plating layers 233 and 243 and the second bump Sn plating layers 234 and 244. For example, the first bump Sn plating layers 233 and 243 and the second bump Sn plating layers 234 and 244 may be in contact with the second bump compound layers 236 and 246.

The first compound layers 135 and 145, the second compound layers 136 and 146, the first bump compound layers 235 and 245, and the second bump compound layers 236 and 246 may include an intermetallic compound including Ni and Sn.

The first compound layers 135 and 145, the second compound layers 136 and 146, the first bump compound layers 235 and 245, and the second bump compound layers 236 and 246 may include a Ni—Sn intermetallic compound, and examples of the Ni—Sn intermetallic compound include Ni₃Sn, Ni₃Sn₂, and Ni₃Sn₄. For example, each of the first compound layers 135 and 145, the second compound layers 136 and 146, the first bump compound layers 235 and 245, and the second bump compound layers 236 and 246 may include at least one selected from the group consisting of Ni₃Sn, Ni₃Sn₂ and Ni₃Sn₄.

Meanwhile, in the first compound layers 135 and 145, the second compound layers 136 and 146, the first bump compound layers 235 and 245, and the second bump compound layers 236 and 246, Ni may exist substantially only in the form of a Ni—Sn intermetallic compound. For example, the ratio of the Sn element to the Ni element in each of the first compound layers 135 and 145, the second compound layers 136 and 146, the first bump compound layers 235 and 245, and the second bump compound layers 236 and 246 may be 1/3 or more. Meanwhile, the upper limit of the ratio of the Sn element to the Ni element in each of the first compound layers 135 and 145, the second compound layers 136 and 146, the first bump compound layers 235 and 245, and the second bump compound layers 236 and 246 is not particularly limited and may vary depending on the type and existence ratio of the Ni—Sn intermetallic compound. In detail, when each of the first compound layers 135 and 145, the second compound layers 136 and 146, the first bump compound layers 235 and 245, and the second bump compound layers 236 and 246 is made of Ni₃Sn₄, the ratio of the Sn element to the Ni element may correspond to 4/3. Therefore, when each of the first compound layers 135 and 145, the second compound layers 136 and 146, the first bump compound layers 235 and 245, and the second bump compound layers 236 and 246 includes at least one selected from the group consisting of Ni₃Sn, Ni₃Sn₂ and Ni₃Sn₄, the ratio of the Sn element to the Ni element in each of the first compound layers 135 and 145, the second compound layers 136 and 146, the first bump compound layers 235 and 245, and the second bump compound layers 236 and 246 may be 1/3 or more and 4/3 or less.

In the composite electronic component according to an embodiment and various embodiments, the compound layer and the plating layer may be distinguished by measuring the range of the existence ratio of the other element to a specific element.

In detail, in the first and second-direction cross section polished to the third-direction center of the composite electronic component, a specific area of the external electrodes 130 and 140 or the bumps 230 and 240 may be analyzed by Scanning Electron Microscopy-Energy Dispersive Spectroscopy (SEM-EDS) to analyze the element ratio of the corresponding area. For example, the Ni plating layers 132 and 142 in the present disclosure may mean an area in which the Ni element exists at 80 at % or more with respect to the total elements excluding oxygen, and the first compound layers 135 and 145 may mean an area in which the ratio of the Sn element to the Ni element is 1/3 or more.

In an embodiment, the first Sn plating layers 133 and 143 may be in contact with the first bump Sn plating layers 233 and 243, the second compound layers 136 and 146 may be in contact with the second bump compound layers 236 and 246, and the second Sn plating layers 134 and 144 may be in contact with the second bump Sn plating layers 234 and 244. Accordingly, the capacitor 100 and the bumps 230 and 240 may be firmly joined.

Referring to FIG. 7, in an embodiment, the first bump compound layers 235 and 245 may have a surface roughness. Meanwhile, the first bump compound layers 235 and 245 may be disposed to surround the main bodies 231 and 242, and in this case, the first bump compound layers 235 and 245 may have surface roughness on all surfaces including the capacitor-side surface.

The surface roughness of the first bump compound layers 235 and 245 may be formed due to high heat applied when forming the first bump compound layers 235 and 245. Meanwhile, if the surface roughness of the first bump compound layers 235 and 245 is excessive, the first bump compound layers 235 and 245 is not formed uniformly, and the Sn plating layer disposed on the first bump compound layers 235 and 245 is formed thickly, which may hinder the effect of alleviating the phenomenon of soldering failure occurring during the process of mounting the composite electronic component on the substrate or alleviating the phenomenon of excessive stress being applied to the composite electronic component. Therefore, it may be preferable that the surface roughness of the surfaces of the first bump compound layers 235 and 245 does not exceed a specific value.

In detail, the ten-point average roughness (Rz) of the first bump compound layers 235 and 245 according to an embodiment may be 1.3 μm or less. The ten-point average roughness (Rz) may be obtained by adding the absolute value of the value (Yp1+Yp2+Yp3+Yp4+Yp5) for the distances from the mean line m of the fifth peak from the highest peak of the extraction sections for a reference length [symbol] , to the absolute value of the value (Yv1 +Yv2 +Yv3 +Yv4 +Yv5) for the distances from the mean line m of the fifth valley from the lowest valley of the extraction sections for the reference length [symbol] , and dividing the added value by 5.

Meanwhile, the method of measuring the ten-point average roughness (Rz) of the first bump compound layers 235 and 245 is not particularly limited. For example, in the first and second-direction cross section of the composite electronic component 100 polished to the third-direction center, the measurement may be made by taking the average value of the ten-point average roughness (Rz) measured in a section 30 μm away from both ends of the second-direction of the capacitor (100)-side surface or the mounting surface-side surface of the first bump compound layers 235 and 245, and in a section 30 μm in the center.

Hereinafter, an example of a method of forming a structure such as an embodiment will be described.

Referring to FIG. 5A, a first bump Ni plating layer 231 and a second bump Sn plating layer 233 may be provided on a bump main body 231. Thereafter, a separate pre-heat treatment may be performed at a temperature of about 160° C. or lower, which is a lower temperature than that in the solder reflow process. Accordingly, as illustrated in FIG. 5B, a first bump compound layer 235 may be formed between the first bump Ni plating layer 232 and the first bump Sn plating layer 233. This pre-heat treatment may be applied not only to the bump but also to the capacitor 100. For example, before attachment of the bumps 230 and 240 and the capacitor 100, the first compound layers 135 and 145 and the first bump compound layers 235 and 245 may already be formed on the capacitor 100 and the bumps 230 and 240.

Since this pre-heat treatment corresponds to a temperature lower than about 270° C., which is the temperature of the solder reflow process, the first compound layers 135 and 145 and the first bump compound layers 235 and 245 may be formed thinner and more uniformly than in the related art.

Next, as illustrated in FIG. 6A, Ni plating layers 137 and 237 and Sn plating layers 134 and 234 may be formed on the capacitor and bump on which the pre-heat treatment has been performed, respectively, for bonding between the capacitor and the bump. Meanwhile, for bonding between the capacitor and the bump, rather than directly mounting on the substrate and performing the solder reflow process in a state like FIG. 6A where the Ni plating layers 137 and 237 and the Sn plating layers 134 and 234 are formed, it may be preferable to perform a separate pre-heat treatment process again. The pre-heat treatment process performed again may be performed at a temperature of about 160° C. or lower, and accordingly, the re-plated Ni plating layers 137 and 237 and Sn plating layers 134 and 234 may react with each other to form second compound layers 136 and 236 as illustrated in FIG. 6B. At this time, when the Ni plating layers 137 and 237 are formed sufficiently thin, the Ni plating layers 137 and 237 in the pre-heat treatment process may all react to form the second compound layers 136 and 236.

As set forth above, according to an embodiment, a problem of mounting defects in composite electronic components may be alleviated by suppressing excessive formation of an outermost Sn plating layer during the process of coupling a capacitor and a bump.

Although the embodiments of the present disclosure have been described in detail above, the present disclosure is not limited by the above-described embodiments and the attached drawings, but is intended to be limited by the appended claims. Accordingly, various forms of substitution, modification, and change may be made by those skilled in the art within the scope that does not depart from the technical idea of the present disclosure described in the claims, and this also falls within the scope of the present disclosure.

In addition, the expression “an(one) embodiment” used in the present disclosure does not mean the same embodiment, and is provided to emphasize and explain each unique feature that is different from the other. However, the embodiments presented above do not exclude being implemented in combination with the features of another embodiment. For example, even if a matter described in a specific embodiment is not described in another embodiment, it can be understood as a description related to another embodiment, unless there is a description that is contrary or contradictory to that matter in another embodiment.

The terms used in the present disclosure are used only to describe one embodiment, and are not intended to limit the present disclosure. In this case, the singular expression includes the plural expression unless the context clearly indicates otherwise.

While example embodiments have been illustrated and described above, it will be apparent to those skilled in the art that modifications and variations could be made without departing from the scope of the present disclosure as defined by the appended claims.

What is claimed is:

1. A composite electronic component comprising:
a capacitor including a body including a dielectric layer and an internal electrode alternately disposed with the dielectric layer, and an external electrode disposed on the body; and
a bump disposed on a lower surface side of the body and connected to the external electrode,
wherein the external electrode includes an electrode layer in contact with the internal electrode, a Ni plating layer disposed on the electrode layer, a first compound layer disposed on the Ni plating layer, a first Sn plating layer disposed on the first compound layer, a second compound layer disposed on the first Sn plating layer, and a second Sn plating layer disposed on the second compound layer, and
the bump includes a main body including a conductive metal, a bump Ni plating layer disposed on the main body, a first bump compound layer disposed on the bump Ni plating layer, a first bump Sn plating layer disposed on the first bump compound layer, a second bump compound layer disposed on the first bump Sn plating layer, and a second bump Sn plating layer disposed on the second bump compound layer.

2. The composite electronic component of claim 1, wherein the first bump compound layer has a surface roughness.

3. The composite electronic component of claim 1, wherein the first bump compound layer has a surface roughness on a capacitor-side surface.

4. The composite electronic component of claim 3, wherein the surface roughness is a ten-point average roughness (Rz), and
the ten-point average roughness (Rz) of the first bump compound layer is 1.3 or less.

5. The composite electronic component of claim 1, wherein the first Sn plating layer and the second Sn plating layer are in contact with the second compound layer.

6. The composite electronic component of claim 1, wherein the first bump Sn plating layer and the second bump Sn plating layer are in contact with the second bump compound layer.

7. The composite electronic component of claim 1, wherein the first compound layer, the second compound layer, the first bump compound layer, and the second bump compound layer each include an intermetallic compound including Ni and Sn.

8. The composite electronic component of claim 7, wherein a ratio of Sn to Ni in each of the first compound layer, the second compound layer, the first bump compound layer, and the second bump compound layer is 1/3 or more and 4/3 or less.

9. The composite electronic component of claim 1, wherein the first Sn plating layer is in contact with the first bump Sn plating layer, the second compound layer is in contact with the second bump compound layer, and the second Sn plating layer is in contact with the second bump Sn plating layer.

10. The composite electronic component of claim 1, wherein the main body includes Cu.

11. The composite electronic component of claim 1, wherein the electrode layer includes Cu.

12. The composite electronic component of claim 1, wherein the main body includes Cu and oxygen (O), wherein a content of O relative to Cu is 0.5 at % or less.
